(19) United States
(12) Patent Application Publication
(10) Pub. No.: US 2005/0093627 A1
(43) Pub. Date: May 5, 2005

(54) Linearity enhanced power amplifier stage

(76) Inventor: Michael W. Vice, El Granada, CA (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/702,021

(22) Filed: Nov. 4, 2003

(51) Int. Cl. H03F 1/26

(52) U.S. Cl. 330/149

(57) ABSTRACT

A power amplifier stage with a mechanism for enhanced linearity. A power amplifier according to the present teachings includes an amplifying device and a circuit that removes a harmonic component of an input signal from a control terminal of the amplifying device. The removal of the harmonic component enhances linearity and enables operation of the power amplifier at higher power levels closer to its compression point.

### BACKGROUND

Power amplifiers may be employed in a variety of electronic systems including communication systems. For example, power amplifiers may be employed in communication systems to generate transmit signals that carry digital information.

A power amplifier may be characterized by its linearity. The linearity of a power amplifier may be depicted visually by plotting a power graph that represents the power of its output signal versus the power of its input signal both expressed in db. The power graph of a linear power amplifier is close to that of a straight line in the operating range of the power amplifier up to a point of compression near the maximum power.

A power amplifiers may exhibit a curvature in its power graph near its point of compression. Unfortunately, such non-linearity near compression may cause distortion in the output signal of the power amplifier at high power levels. In a power amplifier in a digital communication system, for example, such distortion may cause errors in digital data transmission.

The distortion caused by non-linear behavior near the compression point of a power amplifier may be avoided by operating the power amplifier well below its compression point. Unfortunately, such a solution may waste the available power that might otherwise be used to generate a transmit signal. In addition, such a solution may reduce the efficiency of a power amplifier.

### SUMMARY OF THE INVENTION

A power amplifier stage is disclosed with a mechanism for enhanced linearity. A power amplifier according to the present teachings includes an amplifying device and a circuit that removes a harmonic component of an input signal from a control terminal of the amplifying device. The removal of the harmonic component enhances linearity and enables operation of the power amplifier at higher power levels closer to its compression point.

Other features and advantages of the present invention will be apparent from the detailed description that follows.

### BRIEF DESCRIPTION OF THE DRAWINGS

The present invention is described with respect to particular exemplary embodiments thereof and reference is accordingly made to the drawings in which:

FIG. 1 shows a linearity enhanced power amplifier stage according to the present techniques;

FIG. 2 shows one embodiment of the linearity enhanced power amplifier stage.

### DETAILED DESCRIPTION

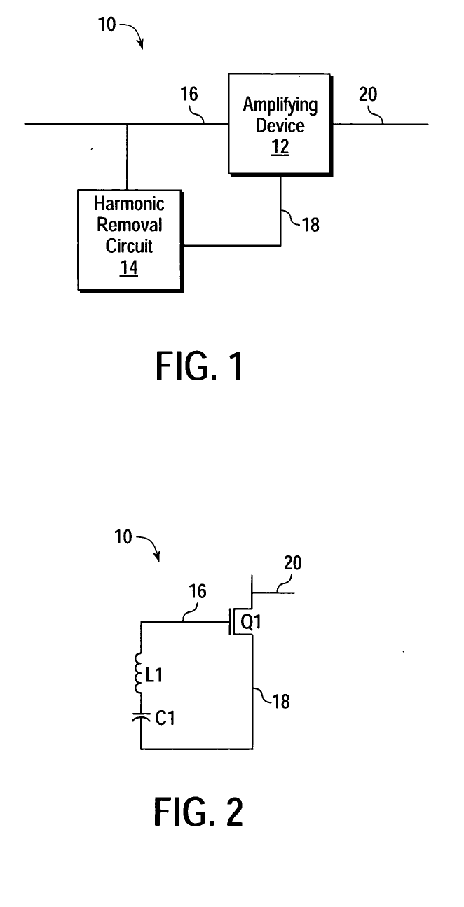

FIG. 1 shows a linearity enhanced power amplifier stage 10 according to the present techniques. The power amplifier stage 10 includes an amplifying device 12 and a harmonic removal circuit 14. The amplifying device 12 may be a field-effect transistor or bipolar junction transistor.

The power amplifier stage 10 generates an output signal at an output node 20 in response to an input signal at a control terminal 16 of the amplifying device 12. The harmonic removal circuit 14 removes a harmonic frequency component from the input signal at the control terminal 16 by effectively producing a short circuit between the control terminal 16 and a terminal 18 of the amplifying device 10. The harmonic removal circuit 14 may include circuit components that are selected and arranged to resonate at the harmonic frequency.

FIG. 2 shows one embodiment of the linearity enhanced power amplifier stage 10. The power amplifier stage 10 includes a field-effect transistor Q1 that functions as its amplifying device.

The harmonic removal circuit 14 includes an inductor L1 and a capacitor C1 that are arranged to enhance the linearity of the power amplifier stage 10. The inductor L1 and the capacitor C1 are connected between the gate and source terminals of the transistor Q1. In embodiments in which the transistor Q1 is a bipolar junction transistor the inductor L1 and the capacitor C1 are connected to the base and emitter.

The inductor L1 and the capacitor C1 are selected so that the combined network of L1 and C1 is resonant at the second harmonic of the fundamental frequency of the input signal presented to the gate of the transistor Q1. With the network in resonance, the gate of the transistor Q1 is effectively shorted to the source at the second harmonic frequency. Thus, the transistor Q1 is prevented by the inductor L1 and the capacitor C1 from generating input second harmonic distortion at its input. The values of L1 and C1 satisfy the following equation.

$$2 {ω}_{o} = \frac{1}{\sqrt{LC}}$$

Other mechanisms within the transistor Q1 may generate second harmonic distortion in the presence of the inductor L1 and the capacitor C1. Nevertheless, the total energy in the second harmonic is reduced by the reduction of input distortion at the frequency of the second harmonic.

When selecting the values for the inductor L1 and the capacitor C1 it is preferable that the selected values do not result in unwanted loading at the fundamental frequency of the input signal to be amplified. If, for example, the nominal gate impedance of the transistor Q1 at the second harmonic is 3 ohms, then the short circuit produced by the inductor L1 and the capacitor C1 at resonance is preferably much less than 3 ohms. When implementing and the inductor L1 and the capacitor C1 it is preferable to achieve a high enough Q that a sufficiently good short circuit is obtained in resonance.

The present techniques may solve the problem of unnecessarily soft compression in power amplifiers. These techniques enable the operation of a power amplifier closer to its compression point, thereby achieving greater efficiency while maintaining linearity. The present techniques maybe employed in combination with other known linearizing methods.

The power amplifier stage 10 may be employed in a modern radio communications system that uses a complex digital modulation scheme as a means of improving bandwidth utilization. Digital modulation may have inherently high peak-to-average envelope contours that must be processed by the power amplifier stage 10 without incurring excessive distortion. The inductor L1 and the capacitor C1 arranged as shown in the power amplifier stage 10 reduce the need to back off of the compression point of the power amplifier 10 to preserve the required linearity. This lessens the reduced efficiency that is found in prior power amplifier stages that back off of the compression point. In battery operated equipment, e.g. mobile phone handsets, low efficiency reduces battery life which is lessened using the present techniques.

The power amplifier stage 10 may be an output stage of a power amplifier or an intermediate stage of a multi-stage power amplifier.

The foregoing detailed description of the present invention is provided for the purposes of illustration and is not intended to be exhaustive or to limit the invention to the precise embodiment disclosed. Accordingly, the scope of the present invention is defined by the appended claims.

1. A power amplifier, comprising:
amplifying device;
circuit that removes a harmonic frequency component from an input signal at a control terminal of the amplifying device.

2. The power amplifier of claim 1, wherein the circuit removes the harmonic frequency component by substantially producing a short circuit between the control terminal and another terminal of the amplifying device.

3. The power amplifier of claim 1, wherein the circuit removes the harmonic frequency component by resonating at the harmonic frequency.

4. The power amplifier of claim 1, wherein the circuit comprises an inductor and a capacitor.

5. The power amplifier of claim 4, wherein the inductor and the capacitor are selected to resonate at the harmonic frequency.

6. The power amplifier of claim 4, wherein the inductor and the capacitor are selected in response to an impedance of the control terminal at a fundamental frequency of the input signal.

7. The power amplifier of claim 1, wherein the harmonic frequency component has a frequency that is twice a fundamental frequency of the input signal.

8. A method for enhancing linearity of a power amplifier, comprising the step of removing a harmonic frequency component from an input signal at a control terminal of an amplifying device in the power amplifier.

9. The method of claim 8, wherein the step of removing comprises the step of removing a harmonic frequency component from an input signal at a control terminal of an amplifying device in an output stage of the power amplifier.

10. The method of claim 8, wherein the step of removing comprises the step of removing a harmonic frequency component from an input signal at a control terminal of an amplifying device in an intermediate stage of the power amplifier.

11. The method of claim 8, wherein the step of removing comprises the step of substantially producing a short circuit between the control terminal and another terminal of the amplifying device.

12. The method of claim 8, wherein the step of removing comprises the step of resonating at the harmonic frequency.

13. The method of claim 8, wherein the step of removing comprises the step of providing an inductor and a capacitor at the control terminal.

14. The method of claim 13, further comprising the step of selecting values for the inductor and the capacitor to resonate at the harmonic frequency.

15. The method of claim 13, further comprising the step of selecting values for the inductor and the capacitor in response to an impedance of the control terminal at a fundamental frequency of the input signal.

16. The method of claim 8, wherein the harmonic frequency component has a frequency that is twice a fundamental frequency of the input signal.
